(19) United States
(12) Patent Application Publication
(10) Pub. No.: US 2006/0141707 A1
(43) Pub. Date: Jun. 29, 2006

(54) Semiconductor memory device and method for fabricating the same

(75) Inventor: Ki-Won Nam, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Hynix SemiConductor, Inc.

(21) Appl. No.: 11/321,160

(22) Filed: Dec. 28, 2005

(30) Foreign Application Priority Data
Dec. 28, 2004 (KR) 2004-0114020

(51) Int. Cl. H01L 21/336

(52) U.S. Cl. 438/257

(57) ABSTRACT

A semiconductor memory device and a method for fabricating a semiconductor memory device are provided. A semiconductor memory device includes a substrate, an inter-layer insulation layer including a storage node contact hole and formed on the substrate, a pair of storage node contact spacers formed on sidewalls of the storage node contact hole and having upper portions recessed to a predetermined depth, a storage node contact plug covering the upper portions of the storage node contact spacers and filling the storage node contact hole, a bottom electrode connected to the storage node contact plug and a dielectric layer and a top electrode stacked on the bottom electrode.

### FIELD OF THE INVENTION

The present invention relates to a fabrication technology of a semiconductor device; and more particularly, to a semiconductor memory device and a method for fabricating the same.

### DESCRIPTION OF RELATED ARTS

As a minimum line width of a semiconductor device has been decreased and a degree of integration of a semiconductor device has also been increased, an area in which a capacitor is formed has been decreased. Accordingly, although the area in which the capacitor is formed has been decreased, the capacitor inside of a cell should ensure the least required capacitance per cell.

Thus, there have been suggested various methods to form a capacitor that has high capacitance within the limited area. One suggested method is to form a dielectric layer with a high electric permittivity level such as Ta₂O₅, Al₂O₃ or HfO₂, replacing a silicon dioxide layer having a dielectric constant (ε) of 3.8 and a nitride layer having a dielectric constant (ε) of 7. Another suggested method is to effectively increase an area of a bottom electrode by forming the bottom electrode with a three-dimensional structure such as a cylinder structure or a concave structure, or by increasing the effective surface area of the bottom electrode by 1.7 fold to 2 fold through growing metastable polysilicon (MPS) grains on the surface of the bottom electrode. Also, a metal-insulator-metal (MIM) method for forming a bottom electrode and a top electrode by using a metal layer has been suggested.

In a dynamic random access memory (DRAM) device with 128 M bits, a method for fabricating a semiconductor memory device having a MIM type capacitor with a typical concave type bottom electrode formed of titanium nitride (TiN) will be described hereinafter.

FIGS. 1A and 1B are cross-sectional views briefly illustrating a method for fabricating a conventional semiconductor device.

As shown in FIG. 1A, an inter-layer insulation layer 12 is formed on an upper portion of a substrate 11. Then, the inter-layer insulation layer 12 is etched, thereby forming a storage node contact hole (not shown) opening a surface of the substrate 11.

Next, a plurality of storage node contact spacers 14 are formed on sidewalls of the storage node contact hole (not shown). Then, a storage node contact plug 13 is buried into the storage node contact hole (not shown) provided with the storage node contact spacers 14. Herein, the storage node contact spacers 14 are formed by using a silicon nitride layer and the storage node contact plug 13 is formed by using polysilicon.

Next, an etch stop insulation layer 15 is formed on the inter-layer insulation layer 12 including the storage node contact plug 13 and then, an insulation layer 16 for a storage node is formed on the etch stop insulation layer 15. Herein, the etch stop insulation layer 15 is formed by using a silicon nitride layer and the insulation layer 16 is formed by using a silicon oxide based layer.

Next, the insulation layer 16 and the etch stop insulation layer 15 are sequentially subjected to a dry etching process, thereby forming a trench 17 opening an upper portion of the storage node contact plug 13.

As shown in FIG. 1B, prior to forming a titanium nitride (TiN) bottom electrode, it is required to form a barrier metal layer in order to form the TiN bottom electrode. Thus, to form the barrier metal layer, titanium (Ti) is deposited on an entire surface including the trench 17 through a physical vapor deposition (CVD) method or a chemical vapor deposition (CVD) method. Afterwards, titanium silicide (TiSiₓ) 18 which is the barrier metal layer is formed through an annealing process and then, non-reacted Ti is removed through a wet etching process.

As described above, by forming TiSiₓ 18, it is possible to reduce a resistance of a layer which the storage node contact plug 13 is contacted with the TiN bottom electrode.

After forming TiSiₓ 18, TiN is deposited on the entire surface including the trench 17 and then, TiN on an upper portion of the insulation layer 16 is selectively removed. Thus, the aforementioned TiN bottom electrode 19 connected to the storage node contact plug 13 inside the trench 17 is formed.

Next, a dielectric layer 20 and a TiN top electrode 21 are sequentially formed on the TiN bottom electrode 19, thereby forming a capacitor.

However, at the step of etching the etch stop insulation layer 15 formed by using the silicon nitride layer during forming the trench 17, a damage in one of the storage node contact spacers 14 is generated. In more details, the storage node spacers 14 formed by using the silicon nitride layer similar to the formation of the etch stop insulation layer 15 are excessively etched due to an overlay between the storage node contact plug 13 and the TiN bottom electrode 19, thereby generating the damage in one of the storage node contact spacers 14. Due to the damage in one of the storage node contact spacers 14, only the storage node contact spacer 14 is additionally and excessively etched in a thickness ranging from approximately 1,000 Å to approximately 1,500 Å in a narrow space of the surroundings of the storage node contact plug 13 and thus, an opening 22 is generated (refer to FIG. 1A).

In such a situation which the opening 22 is generated, the TiN bottom electrode 19 is formed through the deposition and the etch of TiN with step coverage of 50%, and the dielectric layer 20 and the TiN top electrode 21 are formed. At this time, a space 23 into which TiN used for forming the TiN top electrode 21 is deposited is blocked or very narrow. Due to the above mentioned reason, the TiN top electrode 21 cannot be properly deposited and thus, a cruspidal structure 24 is generated on the dielectric layer 20 and the TiN top electrode 21.

Accordingly, as a structural defect of the capacitor which works as a leakage current source of the capacitor is formed, a leakage current property of the capacitor is degraded.

### SUMMARY OF THE INVENTION

It is, therefore, an object of the present invention to provide a semiconductor memory device and capable of removing a leakage current source of a capacitor generated by an opening formed due to a damage in a storage node contact spacer at the step of etching an etch stop insulation layer and a method for fabricating the same.

In accordance with one aspect of the present invention, there is provided with a semiconductor memory device, including: a substrate; an inter-layer insulation layer including a storage node contact hole and formed on the substrate; a pair of storage node contact spacers formed on sidewalls of the storage node contact hole and having upper portions recessed to a predetermined depth; a storage node contact plug covering the upper portions of the storage node contact spacers and filling the storage node contact hole; a bottom electrode connected to the storage node contact plug; and a dielectric layer and a top electrode stacked on the bottom electrode.

In accordance with another aspect of the present invention, there is provided with a method for fabricating a semiconductor memory device, including: forming an inter-layer insulation layer including a storage node contact hole on a substrate; forming a pair of storage node contact spacers of which upper portions are recessed to a predetermined depth on sidewalls of the storage node contact hole; forming a storage node contact plug coring upper portions of the storage node contact spacers and filling the storage node contact hole; forming an etch stop insulation layer on the inter-layer insulation layer and the storage node contact plug; forming a trench opening the storage node contact plug by dry etching the etch stop insulation layer; forming a bottom electrode on the trench; and sequentially forming a dielectric layer and a top electrode on the bottom electrode.

### BRIEF DESCRIPTION OF THE DRAWINGS

The above and other objects and features of the present invention will become better understood with respect to the following description of the preferred embodiments given in conjunction with the accompanying drawings, in which:

FIGS. 1A and 1B are cross-sectional views briefly illustrating a method for fabricating a conventional semiconductor memory device;

FIG. 2 is a cross-sectional view illustrating a semiconductor memory device in accordance with a specific embodiment of the present invention; and

FIGS. 3A to 3D are cross-sectional views illustrating a method for fabricating a semiconductor memory device in accordance with the specific embodiment of the present invention.

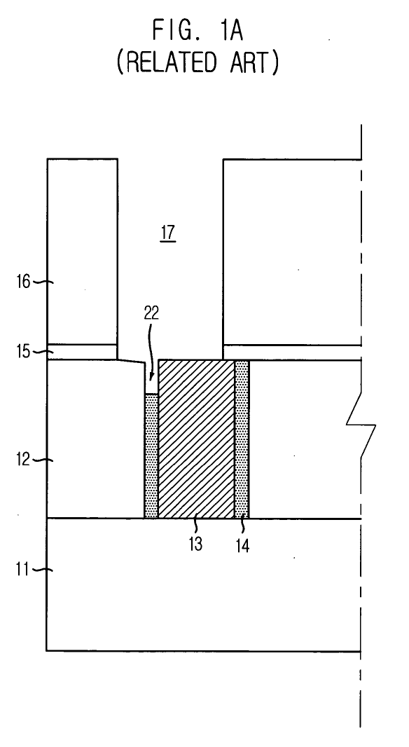

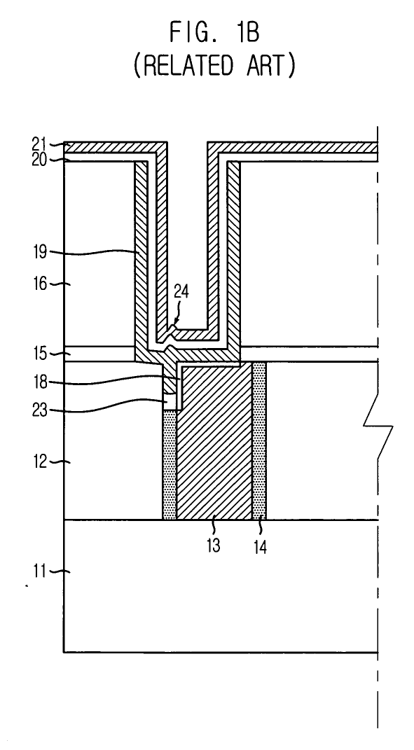

### DETAILED DESCRIPTION OF THE INVENTION

Hereinafter, detailed descriptions of preferred embodiments of the present invention will be provided with reference to the accompanying drawings.

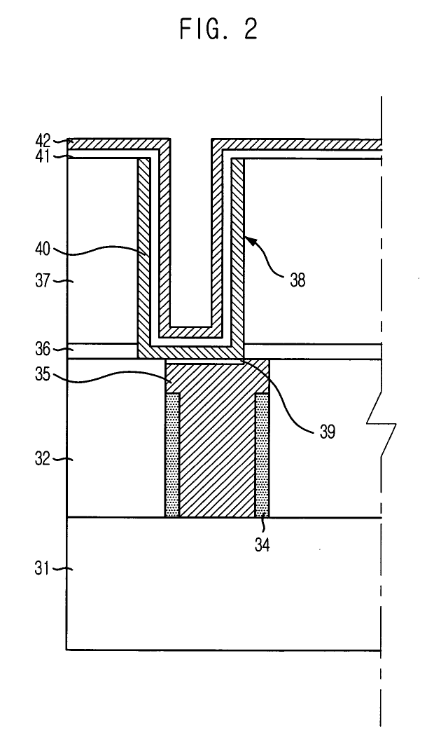

FIG. 2 is a cross-sectional view illustrating a method for fabricating a semiconductor memory device in accordance with a specific embodiment of the present invention.

As shown in FIG. 2, an inter-layer insulation layer 32 is formed on an upper portion of a substrate 31, and a plurality of storage node contact spacers 34 are formed on sidewalls of a storage node contact hole 33 formed inside the inter-layer insulation layer 32. Herein, upper portions of the storage node contact spacers 34 are recessed to a predetermined portion from an upper portion of the storage node contact hole 33.

A storage node contact plug 35 covering the upper portions of the storage node contact spacers 34 is buried inside the storage node contact hole 33, and a barrier metal layer 39 is formed on a surface of the storage node contact plug 35.

A stack structure of an etch stop insulation layer 36 and an insulation layer 37 for a storage node having a trench 38 opening an upper portion of the storage node contact plug 35 is formed on the inter-layer insulation layer 32 including the storage node contact plug 35.

A bottom electrode 40 formed by using titanium nitride (TiN) is formed inside the trench 38, and a dielectric layer 41 and a top electrode 42 formed by using TiN are stacked on the bottom electrode 40.

As described above, the semiconductor memory device in accordance with the first embodiment of the present invention includes the storage node contact plug 35 covering the upper portions of the storage node contact spacers 34, thereby preventing damage in the storage node contact spacers 34 from being generated during an etching process for opening the trench 38.

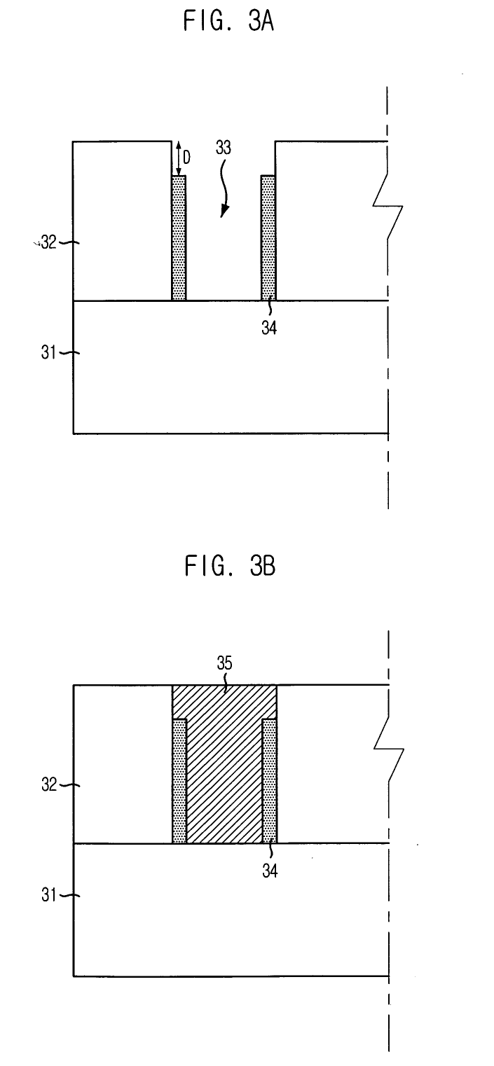

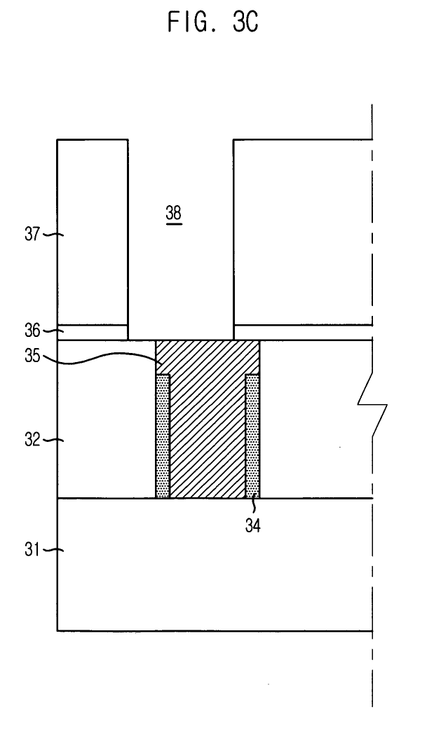

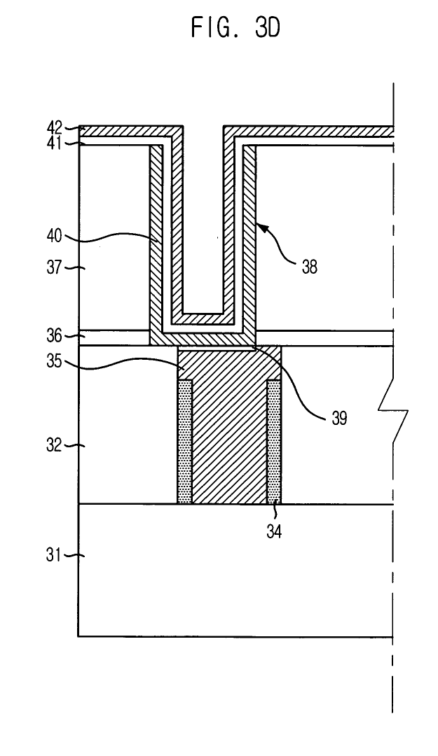

FIGS. 3A to 3D are cross-sectional views illustrating a method for fabricating a semiconductor memory device in accordance with the first embodiment of the present invention shown in FIG. 2.

As shown in FIG. 3A, an inter-layer insulation layer 32 is formed on an upper portion of a substrate 31. At this time, although not shown, prior to the formation of the inter-layer insulation layer 32, various constitution elements including transistors and bit lines are formed and accordingly, the inter-layer insulation layer 32 may be formed in a multiple structure.

Next, a contact mask (not shown) using a photoresist layer is formed on the inter-layer insulation layer 32. Afterwards, the inter-layer insulation layer 32 is etched by using the contact mask as an etch barrier, thereby forming a storage node contact hole 33 opening a surface of the substrate 31. At this time, the surface of the substrate 31 may be a source/drain junction region in which the storage node contact hole 33 opens.

Next, a plurality of storage node contact spacers 34 contacted with sidewalls of the storage node contact hole 33 are formed. A method for forming the storage node contact spacers 34 is as follows.

First, a nitride layer is deposited on an entire surface including the storage node contact hole 33. Afterwards, the nitride layer existing on a surface of the inter-layer insulation layer 32 except for a surface of the storage node contact hole 33 is subjected to a first bulk etch through an etch-back process. Then, the nitride layer is additionally subjected to a second etch, thereby forming the storage node contact spacers 34 of which upper portions are sunk into the inside of the storage node contact hole 33, i.e., the storage node contact spacers 34 with a recess structure.

During forming the storage node contact spacers 34 by using the nitride layer, the first bulk etch and the additionally performed second etch control a recipe not to generate etch damage on the inter-layer insulation layer 32. That is, when the nitride layer is additionally etched in such a situation which the surface of the inter-layer insulation layer 32 is exposed, if an etch selectivity between the inter-layer insulation layer 32 which is an oxide based layer and the nitride layer is identical or the etch selectivity of the inter-layer insulation layer 32 is faster than that of the nitride layer, the storage node contact spacers 34 are not formed inside the storage node contact hole 33. Furthermore, the inter-layer insulation layer 32 gets thinner and thus, an insulation property between a storage node contact plug and a bottom structure, e.g., a bit line, is degraded.

Accordingly, the etch selectivity of the nitride layer should be set faster than that of the oxide layer used as the inter-layer insulation layer 32 in the etching process performed to form the storage node contact spacers 34 in a structure of which the upper portions of the storage node contact spacers 34 are sunk into the inside of the storage node contact hole 33, i.e., the storage node contact spacers 34 having the recess structure, by using the nitride layer. For this, the etching process for forming the storage node contact spacers 34 is performed in a mixed gas atmosphere of carbon tetrafluoride (CF₄) ranging from approximately 10 sccm to approximately 15 sccm, oxygen (O₂) ranging from approximately 5 sccm to approximately 10 sccm, argon (Ar) ranging from approximately 70 sccm to approximately 80 sccm, and trifluoromethane (CHF₃) ranging from approximately 5 sccm to approximately 10 sccm. At this time, a power is approximately 300 W and a pressure is approximately 75 mtorr.

In case of applying the above described recipe, the etch selectivity of the inter-layer insulation layer 32 is approximately 900 Å per minute, and the etch selectivity of the nitride layer is approximately 1,700 Å per minute.

For instance, in case of controlling a recess depth D which the upper portions of the storage node contact spacers 34 are sunk into the inside of the storage node contact hole 33 in a thickness ranging from approximately 500 Å to approximately 1,000 Å, the damage on the inter-layer insulation layer 32 is generated in a thickness ranging from approximately 200 Å to approximately 500 Å. Accordingly, it is possible to form the storage node contact spacers 34 in a structure recessed to the inside of the storage node contact hole 33 in a predetermined thickness as minimizing the damage on the inter-layer insulation layer 32.

As shown in FIG. 3B, a storage node contact plug 35 is buried inside the storage node contact hole 33 provided with the storage node contact spacers 34. At this time, a polysilicon layer is deposited on an entire surface of the above resulting structure until the storage node contact hole 33 provided with the storage node contact spacers 34 is filled. Afterwards, a predetermined portion of the polysilicon layer is polished through a touch chemical mechanical polishing (TCMP) process and then, a dry etch-back process is continuously performed, thereby forming the storage node contact plug 35.

During forming the storage node contact plug 35, since the dry etch-back process which is the last process is performed until the surface of the inter-layer insulation layer 32, the upper portions of the storage node contact spacers 34 are not exposed to the outside of the storage node contact hole 33 due to the storage node contact plug 35. That is, the storage node contact plug 35 has a T-type.

After forming the storage node contact plug 35 through a series of the above described processes, the storage node contact spacers 34 are not exposed to the outside but exist inside the storage node contact hole 33.

As shown in FIG. 3C, an etch stop insulation layer 36 is formed on upper portions of the inter-layer insulation layer 32 provided with the storage node contact plug 35. At this time, the etch stop insulation layer 36 is formed by using a nitride layer.

Next, an insulation layer 37 for a storage node is formed on the etch stop insulation layer 36. At this time, the insulation layer 37 is formed by using a layer selected from the group consisting of a borophospho silicate glass (BPSG) layer, an undoped silicate glass (USG) layer, a high density plasma (HDP) layer, and a tetraethyl orthosilicate (TEOS) layer.

Next, the insulation layer 37 and the etch stop insulation layer 36 are sequentially subjected to a dry etching process, thereby forming a trench 38 opening an upper portion of the storage node contact plug 35.

In more details about the dry etching process for opening the trench 38, the insulation layer 37 is subjected to the dry etching process until the etch is stopped at the etch stop insulation layer 36, and the etch stop insulation layer 36 is continuously subjected to the dry etching process. Thus, a surface of the storage node contact plug 35 is opened.

During the dry etching process for forming the trench 38, particularly the dry etching process subjected to the etch stop insulation layer 36, the dry etching process is excessively performed to completely open the surface of the storage node contact plug 35. In accordance with the first embodiment of the present invention, the upper portions of the storage node contact spacers 34 most vulnerable with respect to damage are covered by the storage node contact plug 35, thereby blocking the storage node contact spacers 34 from being exposed to an etch environment for etching the trench hole 38. Thus, the damage on the storage node contact spacers 34 is prevented.

As a result, in accordance with the first embodiment of the present invention, the storage node contact plug 35 covers the storage node contact spacers 34, thereby preventing the damage on the storage node contact spacers 34 during performing the etching process for forming the trench 38. Accordingly, a bottom portion of the trench 38 can be formed in a flat structure without forming any openings.

As shown in FIG. 3D, prior to forming a bottom electrode formed by using TiN, a barrier metal layer 39 is formed. For instance, Ti is deposited on an entire surface including the trench 38 through a physical vapor deposition (PVD) method or a chemical vapor deposition (CVD) method. Then, an annealing process is employed and thus, titanium silicide (TiSiₓ) is formed and non-reacted Ti is removed through a wet etching process.

Herein, TiSiₓ which is the barrier metal layer 39 is formed by reacting silicon (Si) of the polysilicon layer used for forming the storage node contact plug 35 with Ti. TiSiₓ is not formed on the inter-layer insulation layer 32 around the storage node contact plug 35 or the storage node contact spacers 34.

As described above, if TiSiₓ which is the barrier metal layer 39 is formed, a resistance of a layer which the storage node contact plug 35 is contacted with a subsequent bottom electrode formed by using TiN is reduced.

Next, a storage node isolation process is performed, thereby forming a bottom electrode 40 formed by using TiN connected to the storage node contact plug 35 inside the trench 38.

In more details about the storage node isolation process to form the bottom electrode 40, TiN is deposited on the insulation layer 37 including the trench 38 trough a CVD method, a PVD method or an atomic layer deposition (ALD) method. Then, TiN formed only on an upper surface of the insulation layer 37 except for the trench 38 is removed through a CMP method or an etch-back process, thereby forming the bottom electrode 40. Herein, there is a possibility that particles such as abrasives or etched particles are attached to the inside of the bottom electrode 40 during the CMP process or the etch-back process. Thus, the inside of the trench 38 is filled by using a photoresist layer with a good step coverage and then, TiN is subjected to the CMP process or the etch-back process until the surface of the insulation layer 37 is exposed. Afterwards, the photoresist layer is subjected to ashing.

Next, a dielectric layer 41 and a top electrode 42 formed by using TiN are sequentially formed on the bottom electrode 40, thereby forming a capacitor. At this time, the dielectric layer 40 is formed by using a material selected from the group consisting of ONO, hafnium oxide (HfO₂), aluminum oxide (Al₂O₃), and tantalum oxide (Ta₂O₅) . Since the bottom portion of the trench 38 is flat, a deposition process which is not sensitive to the step coverage can be used. Furthermore, the top electrode 42 can use a deposition process which is not sensitive to the step coverage. For instance, a CVD method, a PVD method or an ALD method is used.

In accordance with the aforementioned embodiments of the present invention, a flat structure is formed around a storage node contact plug 35 recessed during forming a dielectric layer 41 and a top electrode 42 formed by using TiN and thus, a space in which TiN used for forming the top electrode 42 is not blocked, and a cruspidal structure is not generated on the dielectric layer 41 and the top electrode 42.

Herein, although a bottom electrode formed by using TiN is exemplified, the present invention can be applied to fabrication processes of all types of capacitors using a nitride based material to form a storage node contact spacer.

In accordance with the present invention, upper portions of storage node contact spacers are completely covered by a storage node contact plug and thus, a damage generated on the storage node contact spacers around the storage node contact plug during etching an etch stop insulation layer can be prevented. Accordingly, it is possible to provide an effect of improving yields of products by removing a leakage current source.

As the leakage current source is removed, it is possible to obtain effects of securing a design rule according to a fine pattern and maximizing a process margin.

The present application contains subject matter related to the Korean patent application Nos. KR 2004-0114020, filed in the Korean Patent Office on Dec. 28, 2004, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A semiconductor memory device, comprising:
a substrate;
an inter-layer insulation layer including a storage node contact hole and formed on the substrate;
a pair of storage node contact spacers formed on sidewalls of the storage node contact hole and having upper portions recessed to a predetermined depth;
a storage node contact plug covering the upper portions of the storage node contact spacers and filling the storage node contact hole;
a bottom electrode connected to the storage node contact plug; and
a dielectric layer and a top electrode stacked on the bottom electrode.

2. The semiconductor memory device of claim 1, wherein the upper portions of the storage node contact spacers are recessed to a thickness ranging from approximately 500 Å to approximately 1,000 Å.

3. The semiconductor memory device of claim 2, wherein the storage node contact spacers include a nitride based material.

4. The semiconductor memory device of claim 1, wherein the storage node contact plug includes polysilicon.

5. A method for fabricating a semiconductor memory device, comprising:
forming an inter-layer insulation layer including a storage node contact hole on a substrate;
forming a pair of storage node contact spacers of which upper portions are recessed to a predetermined depth on sidewalls of the storage node contact hole;
forming a storage node contact plug coring upper portions of the storage node contact spacers and filling the storage node contact hole;
forming an etch stop insulation layer on the inter-layer insulation layer and the storage node contact plug;
forming a trench opening the storage node contact plug by dry etching the etch stop insulation layer;
forming a bottom electrode on the trench; and
sequentially forming a dielectric layer and a top electrode on the bottom electrode.

6. The method of claim 5, wherein the forming of the storage node contact spacers includes:
forming a nitride layer on a surface of the inter-layer insulation layer including the storage node contact hole;
performing a first etching process on the nitride layer until the surface of the inter-layer insulation layer is exposed; and
performing a second etching process on the nitride layer such that the nitride layer is recessed to a predetermined depth inside the storage node contact hole.

7. The method of claim 6, wherein the first etching process and the second etching process are performed by setting an etch selectivity of the nitride layer faster than that of the inter-layer insulation layer.

8. The method of claim 7, wherein the first etching process and the second etching process are performed in an atmosphere of a mixed gas including tetrafluoromethane (CF₄), oxygen (O₂), argon (Ar), and trifluoromethane (CHF₃).

9. The method of claim 5, wherein the predetermined recess depth of the storage node contact spacers ranges from approximately 500 Å to approximately 1,000 Å.

10. The method of claim 6, wherein the predetermined recess depth of the storage node contact spacers ranges from approximately 500 Å to approximately 1,000 Å.
